(19) United States
(12) Patent Application Publication
(10) Pub. No.: US 2026/0271346 A1
(43) Pub. Date: Sep. 10, 2026

(54) TRANSISTOR STRUCTURE

(71) Applicant: Powerchip Semiconductor Manufacturing Corporation, Hsinchu (TW)

(72) Inventors: Meng-Han Lin, Hsinchu City (TW); Yu-Chang Lin, Hsinchu (TW); Ju-Chun Tien, Hsinchu (TW); Yu Huan Sa, Hsinchu (TW); Ying Chia Lin, Hsinchu City (TW)

(73) Assignee: Powerchip Semiconductor Manufacturing Corporation, Hsinchu (TW)

(21) Appl. No.: 19/096,743

(22) Filed: Apr. 1, 2025

(30) Foreign Application Priority Data
Mar. 7, 2025 (TW) 114108525

(51) Int. Cl. H10D 30/69

(52) U.S. Cl. CPC H10D 30/701

(57) ABSTRACT

A transistor structure including a substrate, a gate, a first doped region, a second doped region, a gate dielectric layer, and a dipole layer is provided. The substrate includes an active region. The active region includes a first edge and a second edge opposite to each other. The gate is located on the substrate in the active region. The gate overlaps the first edge and the second edge. The first doped region and the second doped region are located in the substrate in the active region on two sides of the gate. The gate dielectric layer is located between the gate and the substrate. The dipole layer is located between the gate and the gate dielectric layer. The dipole layer includes a first opening and a second opening. The first opening overlaps the first edge. The second opening overlaps the second edge.

### CROSS-REFERENCE TO RELATED APPLICATION

This application claims the priority benefit of Taiwan application serial no. 114108525, filed on March 7, 2025. The entirety of the above-mentioned patent application is hereby incorporated by reference herein and made a part of this specification.

### BACKGROUND

### Technical Field

The invention relates to a semiconductor structure, and particularly relates to a transistor structure.

### Description of Related Art

The transistor device is one of the main devices in the integrated circuit. The transistor device includes a gate and a source region and a drain region located in a substrate on two sides of the gate. However, in some transistor devices, compared with the central region of the active region, the transistor device has a lower absolute value of threshold voltage (Vt) in the edge region of the active region, so the current double hump effect is easily generated, which has an adverse effect on the electrical property of the transistor device.

### SUMMARY

The invention provides a transistor structure, which can effectively reduce the current double hump effect, thereby preventing the current double hump effect from causing the adverse effect on the electrical property of the transistor structure.

The invention provides a transistor structure, which includes a substrate, a gate, a first doped region, a second doped region, a gate dielectric layer, and a dipole layer. The substrate includes an active region. The active region includes a first edge and a second edge opposite to each other. The gate is located on the substrate in the active region. The gate overlaps the first edge and the second edge. The first doped region and the second doped region are located in the substrate in the active region on two sides of the gate. The gate dielectric layer is located between the gate and the substrate. The dipole layer is located between the gate and the gate dielectric layer. The dipole layer includes a first opening and a second opening. The first opening overlaps the first edge. The second opening overlaps the second edge.

According to an embodiment of the invention, in the transistor structure, the dipole layer may extend from the first edge to the second edge. The dipole layer may overlap the first edge and the second edge.

According to an embodiment of the invention, in the transistor structure, in a direction from the first edge toward the second edge, the first opening and the second opening may be aligned with each other.

According to an embodiment of the invention, in the transistor structure, in a direction from the first edge toward the second edge, the first opening and the second opening are not aligned with each other.

According to an embodiment of the invention, in the transistor structure, in a direction from the first doped region toward the second doped region, the first opening may extend through the dipole layer and the second opening may extend through the dipole layer to divide the dipole layer into portions separated from each other.

According to an embodiment of the invention, in the transistor structure, the dipole layer may include a plurality of the first openings and a plurality of the second openings. The plurality of the first openings may overlap the first edge. The plurality of the second openings may overlap the second edge.

According to an embodiment of the invention, in the transistor structure, the dipole layer may be a negative polarity dipole (n-dipole) layer or a positive polarity dipole (p-dipole) layer.

According to an embodiment of the invention, in the transistor structure, the material of the negative polarity dipole layer is, for example, lanthanum oxide (La₂O₃).

According to an embodiment of the invention, in the transistor structure, the material of the positive polarity dipole layer is, for example, aluminum oxide (Al₂O₃).

According to an embodiment of the invention, in the transistor structure, the gate may be a metal gate. The gate dielectric layer may include a high dielectric constant (high-k) dielectric layer.

According to an embodiment of the invention, the transistor structure may further include an isolation structure. The isolation structure is located in the substrate. The isolation structure may define the active region. The first opening may overlap the isolation structure. The second opening may overlap the isolation structure.

The invention provides another transistor structure, which includes a substrate, a gate, a first doped region, a second doped region, a gate dielectric layer, a first island-shaped dipole layer, and a second island-shaped dipole layer. The substrate includes an active region. The active region includes a first edge and a second edge opposite to each other. The gate is located on the substrate in the active region. The gate overlaps the first edge and the second edge. The first doped region and the second doped region are located in the substrate in the active region on two sides of the gate. The gate dielectric layer is located between the gate and the substrate. The first island-shaped dipole layer and the second island-shaped dipole layer are located between the gate and the gate dielectric layer and are separated from each other. The first island-shaped dipole layer overlaps the first edge. The second island-shaped dipole layer overlaps the second edge.

According to another embodiment of the invention, in the transistor structure, in a direction from the first edge toward the second edge, the first island-shaped dipole layer and the second island-shaped dipole layer may be aligned with each other.

According to another embodiment of the invention, in the transistor structure, in a direction from the first edge toward the second edge, the first island-shaped dipole layer and the second island-shaped dipole layer are not aligned with each other.

According to another embodiment of the invention, in the transistor structure, in a direction from the first doped region toward the second doped region, the first island-shaped dipole layer may extend to two opposite edges of the gate, and the second island-shaped dipole layer may extend to the two opposite edges of the gate.

According to another embodiment of the invention, the transistor structure may include a plurality of the first island-shaped dipole layers and a plurality of the second island-shaped dipole layers. The plurality of the first island-shaped dipole layers may overlap at the first edge. The plurality of the second island-shaped dipole layers may overlap at the second edge.

According to another embodiment of the invention, in the transistor structure, the first island-shaped dipole layer and the second island-shaped dipole layer may be positive polarity dipole layers.

According to another embodiment of the invention, in the transistor structure, the first island-shaped dipole layer and the second island-shaped dipole layer may be negative polarity dipole layers.

According to another embodiment of the invention, in the transistor structure, the gate may be a metal gate. The gate dielectric layer may include a high-k dielectric layer.

According to another embodiment of the invention, the transistor structure may further include an isolation structure. The isolation structure is located in the substrate. The isolation structure may define the active region. The first island-shaped dipole layer may overlap the isolation structure. The second island-shaped dipole layer may overlap the isolation structure.

Based on the above description, in a transistor structure according to some embodiments of the invention, a dipole layer is located between a gate and a gate dielectric layer, the dipole layer includes a first opening and a second opening, the first opening overlaps a first edge of an active region, and the second opening overlaps a second edge of the active region. Therefore, the absolute value of the threshold voltage of the transistor structure in an edge region adjacent to the first edge of the active region can be increased, and the absolute value of the threshold voltage of the transistor structure in an edge region adjacent to the second edge of the active region can be increased. In this way, the current double hump effect can be effectively reduced, thereby preventing the current double hump effect from causing the adverse effect on the electrical property of the transistor structure.

In addition, in the transistor structure according to another embodiments of the invention, a first island-shaped dipole layer and a second island-shaped dipole layer are located between a gate and a gate dielectric layer and are separated from each other, the first island-shaped dipole layer overlaps a first edge of an active region, and the second island-shaped dipole layer overlaps a second edge of the active region. Therefore, the absolute value of the threshold voltage of the transistor structure in an edge region adjacent to the first edge of the active region can be increased, and the absolute value of the threshold voltage of the transistor structure in an edge region adjacent to the second edge of the active region can be increased. In this way, the current double hump effect can be effectively reduced, thereby preventing the current double hump effect from causing the adverse effect on the electrical property of the transistor structure.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a transistor structure according to some embodiments of the invention.

FIG. 2 is a cross-sectional view taken along section line I-I’ and section line II-II’ in FIG. 1.

FIG. 3 is a top view of a transistor structure according to other embodiments of the invention.

FIG. 4 is a top view of a transistor structure according to other embodiments of the invention.

FIG. 5 is a top view of a transistor structure according to other embodiments of the invention.

FIG. 6 is a top view of a transistor structure according to other embodiments of the invention.

FIG. 7 is a cross-sectional view taken along section line III-III’ and section line IV-IV’ in FIG. 6.

FIG. 8 is a top view of a transistor structure according to other embodiments of the invention.

FIG. 9 is a top view of a transistor structure according to other embodiments of the invention.

FIG. 10 is a top view of a transistor structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. Furthermore, the features in the top view and the features in the cross-sectional view are not drawn to the same scale. In fact, the dimensions of the various features may be arbitrarily increased or reduced for clarity of discussion.

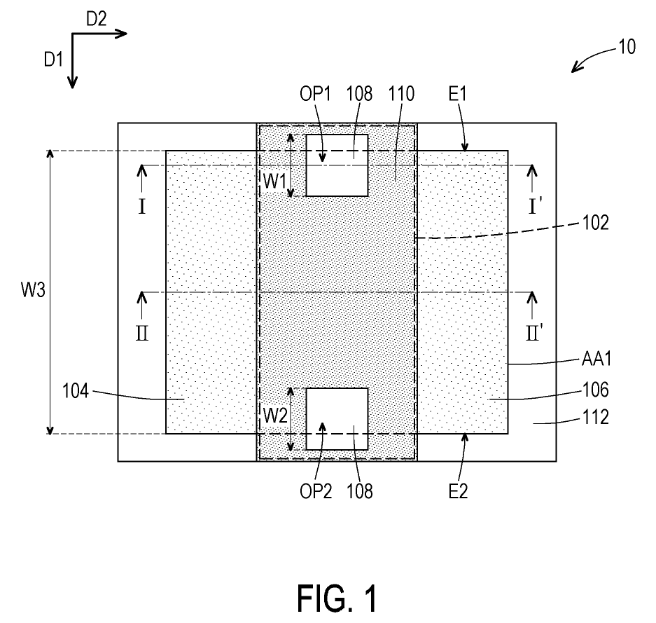

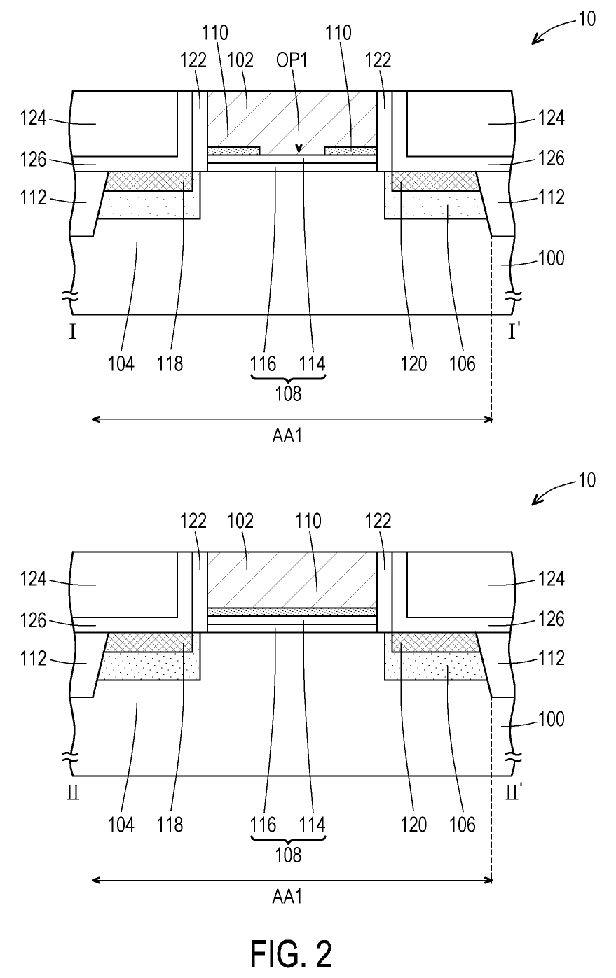

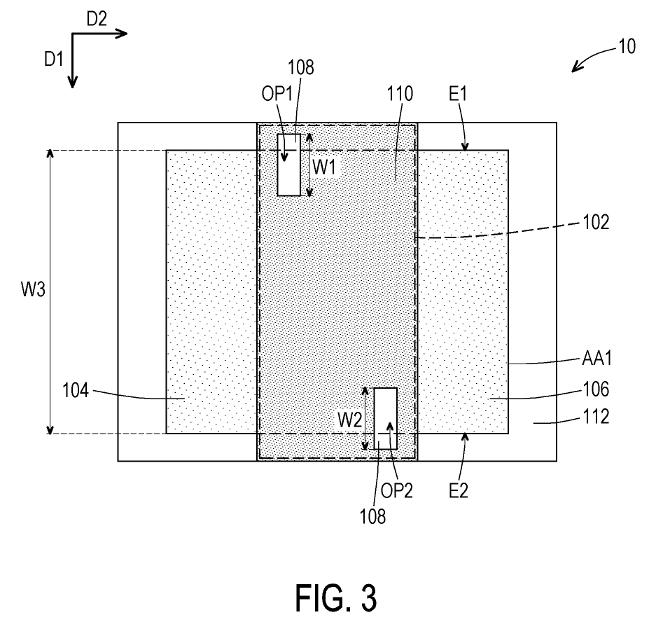

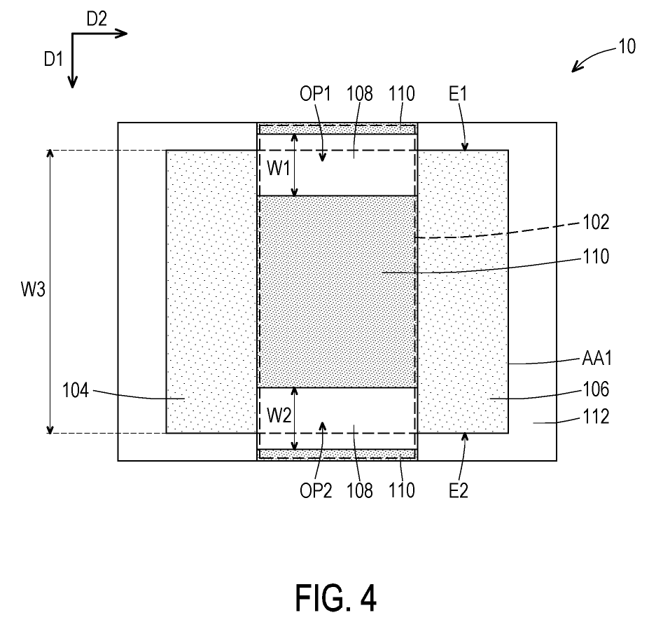

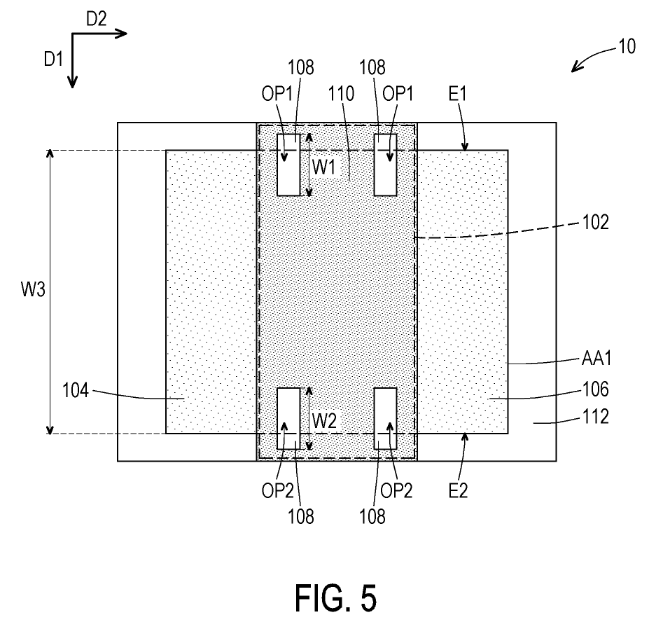

FIG. 1 is a top view of a transistor structure according to some embodiments of the invention. FIG. 2 is a cross-sectional view taken along section line I-I’ and section line II-II’ in FIG. 1. In FIG. 1, some components in FIG. 2 are omitted to clearly illustrate the configuration relationship between the components in FIG. 1. FIG. 3 is a top view of a transistor structure according to other embodiments of the invention. FIG. 4 is a top view of a transistor structure according to other embodiments of the invention. FIG. 5 is a top view of a transistor structure according to other embodiments of the invention.

Referring to FIG. 1 and FIG. 2, a transistor structure 10 includes a substrate 100, a gate 102, a doped region 104, a doped region 106, a gate dielectric layer 108, and a dipole layer 110. The transistor structure 10 may be an N-type metal oxide semiconductor (NMOS) transistor structure or a P-type metal oxide semiconductor (PMOS) transistor structure.

The substrate 100 includes an active region AA1. The active region AA1 includes an edge E1 and an edge E2 opposite to each other. In some embodiments, the substrate 100 may be a semiconductor substrate such as a silicon substrate. In some embodiments, the transistor structure 10 may further include an isolation structure 112. The isolation structure 112 is located in the substrate 100. The isolation structure 112 may define the active region AA1. In some embodiments, the isolation structure 112 is, for example, a shallow trench isolation (STI) structure. In some embodiments, the material of the isolation structure 112 is, for example, silicon oxide.

The gate 102 is located on the substrate 100 in the active region AA1. The gate 102 overlaps the edge E1 and the edge E2. The gate 102 may extend from the edge E1 to the edge E2. In some embodiments, the gate 102 may overlap the isolation structure 112. The gate 102 may be a single-layer structure or a multilayer structure. In some embodiments, the gate 102 may be a metal gate. In some embodiments, the material of the gate 102 is, for example, W, TiN, TaN, WN, Ti, Ag, TaAlC, TiAlN, or a combination thereof.

The doped region 104 and the doped region 106 are located in the substrate 100 in the active region AA1 on two sides of the gate 102. In some embodiments, the doped region 104 and the doped region 106 may be used as source/drain regions.

The gate dielectric layer 108 is located between the gate 102 and the substrate 100. The gate dielectric layer 108 may be a single-layer structure or a multilayer structure. In some embodiments, the gate dielectric layer 108 may include a high-k dielectric layer 114. The high-k dielectric layer 114 is located between the gate 102 and the substrate 100. In some embodiments, the material of the high-k dielectric layer 114 is, for example, metal oxide. In some embodiments, the gate dielectric layer 108 may further include an interfacial layer 116. The interfacial layer 116 is located between the high-k dielectric layer 114 and the substrate 100. In some embodiments, the material of the interfacial layer 116 is, for example, silicon oxide.

The transistor structure 10 may further include a metal silicide layer 118 and a metal silicide layer 120. The metal silicide layer 118 is located on the doped region 104. The metal silicide layer 120 is located on the doped region 106. In some embodiments, the material of the metal silicide layer 118 and the material of the metal silicide layer 120 are, for example, cobalt silicide (CoSi) or nickel silicide (NiSi). The transistor structure 10 may further include a spacer 122. The spacer 122 is located on a sidewall of the gate 102. The spacer 122 may be a single-layer structure or a multilayer structure. In some embodiments, the material of the spacer 122 is, for example, silicon oxide, silicon nitride, or a combination thereof. The transistor structure 10 may further include a dielectric layer 124. The dielectric layer 124 is located on the isolation structure 112, the metal silicide layer 118, and the metal silicide layer 120. In some embodiments, the material of the dielectric layer 124 is, for example, silicon oxide, silicon nitride, or a combination thereof. The transistor structure 10 may further include a stop layer 126. The stop layer 126 is located between the dielectric layer 124 and the spacer 122, between the dielectric layer 124 and the isolation structure 112, between the dielectric layer 124 and the metal silicide layer 118, and between the dielectric layer 124 and the metal silicide layer 120. In some embodiments, the material of the stop layer 126 is, for example, silicon oxide, silicon nitride, or a combination thereof.

The dipole layer 110 is located between the gate 102 and the gate dielectric layer 108. The dipole layer 110 may extend from the edge E1 to the edge E2. The dipole layer 110 may overlap the edge E1 and the edge E2. In some embodiments, the dipole layer 110 may overlap the isolation structure 112. In some embodiments, the dipole layer 110 may be a negative polarity dipole layer or a positive polarity dipole layer. In some embodiments, the material of the negative polarity dipole layer is, for example, lanthanum oxide. In some embodiments, the material of the positive polarity dipole layer is, for example, aluminum oxide. In some embodiments, when the transistor structure 10 is an NMOS transistor structure and the dipole layer 110 is a negative polarity dipole layer, the dipole layer 110 can reduce the absolute value of the threshold voltage of the transistor structure 10. In some embodiments, when the transistor structure 10 is a PMOS transistor structure and the dipole layer 110 is a positive polarity dipole layer, the dipole layer 110 can reduce the absolute value of the threshold voltage of the transistor structure 10.

The dipole layer 110 includes an opening OP1 and an opening OP2. In some embodiments, the opening OP1 and the opening OP2 may expose the gate dielectric layer 108. In some embodiments, the gate 102 may fill the opening OP1 and the opening OP2 and may be connected to the gate dielectric layer 108. In some embodiments, the opening OP1 may overlap the isolation structure 112. The opening OP2 may overlap the isolation structure 112. The opening OP1 the overlaps the edge E1. The Opening OP2 overlaps the edge E2. When the transistor structure 10 is an NMOS transistor structure and the dipole layer 110 is a negative polarity dipole layer, since the dipole layer 110 has the opening OP1 overlapping the edge E1 and the opening OP2 overlapping the edge E2, the absolute value of the threshold voltage of the transistor structure 10 in an edge region adjacent to the edge E1 of the active region AA1 can be increased, and the absolute value of the threshold voltage of the transistor structure 10 in an edge region adjacent to the edge E2 of the active region AA1 can be increased. In addition, when the transistor structure 10 is a PMOS transistor structure and the dipole layer 110 is a positive polarity dipole layer, since the dipole layer 110 has the opening OP1 overlapping the edge E1 and the opening OP2 overlapping the edge E2, the absolute value of the threshold voltage of the transistor structure 10 in an edge region adjacent to the edge E1 of the active region AA1 can be increased, and the absolute value of the threshold voltage of the transistor structure 10 in an edge region adjacent to the edge E2 of the active region AA1 can be increased.

In some embodiments, in a direction D1 from the edge E1 toward the edge E2, the opening OP1 may have a width W1, the opening OP2 may have a width W2, and the active region AA1 may have a width W3. In some embodiments, the width W1 may be 5% to 30% of the width W3. In some embodiments, the width W2 may be 5% to 30% of the width W3.

In the present embodiment, as shown in FIG. 1, in the direction D1 from the edge E1 toward the edge E2, the opening OP1 and the opening OP2 may be aligned with each other, but the invention is not limited thereto. In other embodiments, as shown in FIG. 3, in the direction D1 from the edge E1 toward the edge E2, the opening OP1 and the opening OP2 are not aligned with each other.

In the present embodiment, as shown in FIG. 1, the opening OP1 and the opening OP2 may be surrounded by the dipole layer 110, but the invention is not limited thereto. In the present embodiment, as shown in FIG. 1, in a direction D2 from the doped region 104 toward the doped region 106, the opening OP1 does not pass through the dipole layer 110, and the opening OP2 does not pass through the dipole layer 110. In other embodiments, as shown in FIG. 4, in the direction D2 from the doped region 104 toward the doped region 106, the opening OP1 may extend through the dipole layer 110 and the opening OP2 may extend through the dipole layer 110 to divide the dipole layer 110 into portions separated from each other.

In the present embodiment, as shown in FIG. 1, in the dipole layer 110, the number of the openings OP1 is, for example, one, and the number of the openings OP2 is, for example, one, but the invention is not limited thereto. In other embodiments, as shown in FIG. 5, the dipole layer 110 may include a plurality of the openings OP1 and a plurality of the openings OP2. The plurality of the openings OP1 may overlap the edge E1. The plurality of the openings OP2 may overlap the edge E2. In addition, when the dipole layer 110 includes the plurality of the openings OP1 and the plurality of the openings OP2, the number of the plurality of the openings OP1 and the number of the plurality of the openings OP2 are not limited to the number shown in FIG. 5. Furthermore, the top-view shape of the opening OP1 and the top-view shape of the opening OP2 are not limited to the shapes shown in the figures.

In FIG. 1 to FIG. 5, the same or similar components are denoted by the same reference symbols, and the description thereof is omitted.

Based on the above embodiments, in the transistor structure 10, the dipole layer 110 is located between the gate 102 and the gate dielectric layer 108. The dipole layer 110 includes the opening OP1 and the opening OP2. The opening OP1 overlaps the edge E1 of the active region AA1, and the opening OP2 overlaps the edge E2 of the active region AA1. Therefore, the absolute value of the threshold voltage of the transistor structure 10 in an edge region adjacent to the edge E1 of the active region AA1 can be increased, and the absolute value of the threshold voltage of the transistor structure 10 in an edge region adjacent to the edge E2 of the active region AA1 can be increased. In this way, the current double hump effect can be effectively reduced, thereby preventing the current double hump effect from causing the adverse effect on the electrical property of the transistor structure 10.

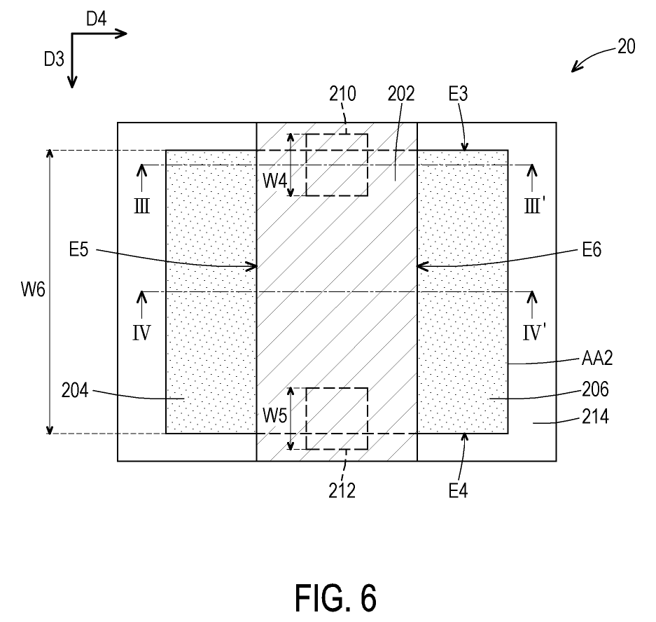

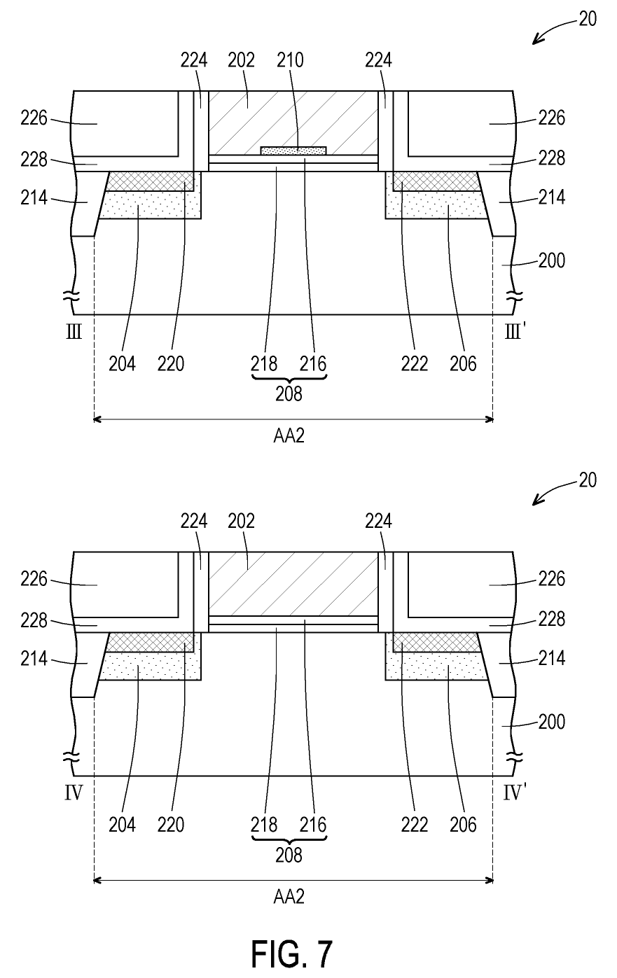

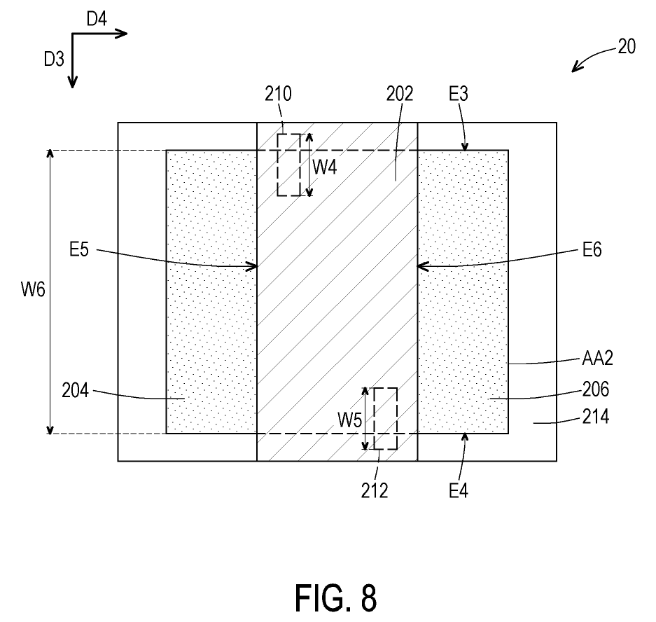

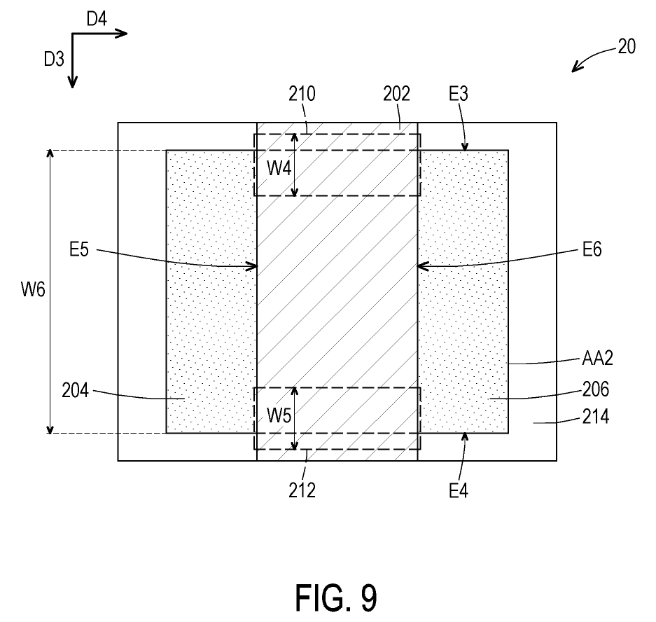

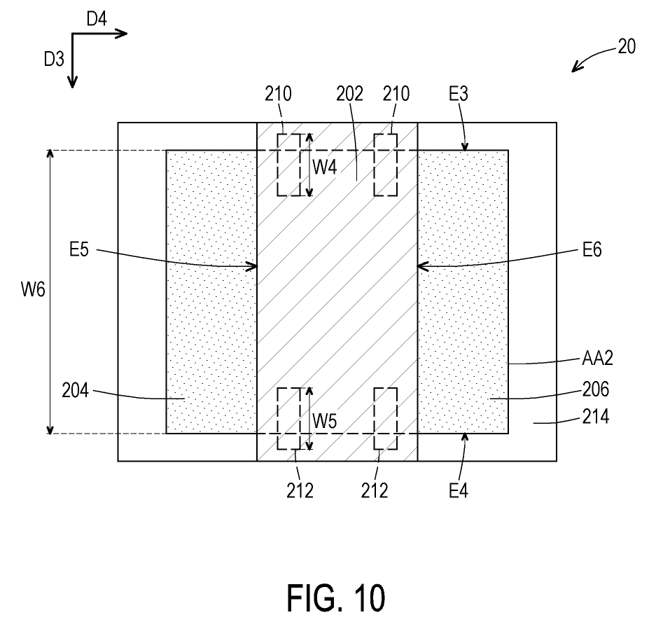

FIG. 6 is a top view of a transistor structure according to other embodiments of the invention. FIG. 7 is a cross-sectional view taken along section line III-III’ and section line IV-IV’ in FIG. 6. In FIG. 6, some components in FIG. 7 are omitted to clearly illustrate the configuration relationship between the components in FIG. 6. FIG. 8 is a top view of a transistor structure according to other embodiments of the invention. FIG. 9 is a top view of a transistor structure according to other embodiments of the invention. FIG. 10 is a top view of a transistor structure according to other embodiments of the invention.

Referring to FIG. 6 and FIG. 7, a transistor structure 20 includes a substrate 200, a gate 202, a doped region 204, a doped region 206, a gate dielectric layer 208, an island-shaped dipole layer 210, and an island-shaped dipole layer 212. The transistor structure 10 may be an NMOS transistor structure or a PMOS transistor structure.

The substrate 200 includes an active region AA2. The active region AA2 includes an edge E3 and an edge E4 opposite to each other. In some embodiments, substrate 200 may be a semiconductor substrate such as a silicon substrate. In some embodiments, the transistor structure 20 may further include an isolation structure 214. The isolation structure 214 is located in the substrate 200. The isolation structure 214 may define the active region AA2. In some embodiments, the isolation structure 214 is, for example, a shallow trench isolation structure. In some embodiments, the material of the isolation structure 214 is, for example, silicon oxide.

The gate 202 is located on the substrate 200 in the active region AA2. The gate 202 overlaps the edge E3 and the edge E4. The gate 202 may extend from the edge E3 to the edge E4. In some embodiments, the gate 202 may overlap the isolation structure 214. The gate 202 may be a single-layer structure or a multilayer structure. In some embodiments, the gate 202 may be a metal gate. In some embodiments, the material of the gate 202 is, for example, W, TiN, TaN, WN, Ti, Ag, TaAlC, TiAlN, or a combination thereof.

The doped region 204 and the doped region 206 are located in the substrate 200 in the active region AA2 on two sides of the gate 202. In some embodiments, the doped region 204 and the doped region 206 may be used as source/drain regions.

The gate dielectric layer 208 is located between the gate 202 and the substrate 200. The gate dielectric layer 208 may be a single-layer structure or a multilayer structure. In some embodiments, the gate dielectric layer 208 may include a high-k dielectric layer 216. The high-k dielectric layer 216 is located between the gate 202 and the substrate 200. In some embodiments, the material of the high-k dielectric layer 216 is, for example, metal oxide. In some embodiments, the gate dielectric layer 208 may further include an interfacial layer 218. The interfacial layer 218 is located between the high-k dielectric layer 216 and the substrate 200. In some embodiments, the material of the interfacial layer 218 is, for example, silicon oxide.

The transistor structure 20 may further include a metal silicide layer 220 and a metal silicide layer 222. The metal silicide layer 220 is located on the doped region 204. The metal silicide layer 222 is located on the doped region 206. In some embodiments, the material of the metal silicide layer 220 and the material of the metal silicide layer 222 are, for example, cobalt silicide (CoSi) or nickel silicide (NiSi). The transistor structure 20 may further include a spacer 224. The spacer 224 is located on a sidewall of the gate 202. The spacer 224 may be a single-layer structure or a multilayer structure. In some embodiments, the material of the spacer 224 is, for example, silicon oxide, silicon nitride, or a combination thereof. The transistor structure 20 may further include a dielectric layer 226. The dielectric layer 226 is located on the isolation structure 214, the metal silicide layer 220, and the metal silicide layer 222. In some embodiments, the material of the dielectric layer 226 is, for example, silicon oxide, silicon nitride, or a combination thereof. The transistor structure 20 may further include a stop layer 228. The stop layer 228 is located between the dielectric layer 226 and the spacer 224, between the dielectric layer 226 and the isolation structure 214, between the dielectric layer 226 and the metal silicide layer 220, and between the dielectric layer 226 and the metal silicide layer 222. In some embodiments, the material of the stop layer 228 is, for example, silicon oxide, silicon nitride, or a combination thereof.

The island-shaped dipole layer 210 and the island-shaped dipole layer 212 are located between the gate 202 and the gate dielectric layer 208 and are separated from each other. The island-shaped dipole layer 210 overlaps the edge E3. The island-shaped dipole layer 212 overlaps the edge E4. The island-shaped dipole layer 210 may overlap the isolation structure 214. The island-shaped dipole layer 212 may overlap the isolation structure 214. In some embodiments, the island-shaped dipole layer 210 and the island-shaped dipole layer 212 may be positive polarity dipole layers. In some embodiments, the material of the positive polarity dipole layer is, for example, aluminum oxide. In some embodiments, the island-shaped dipole layer 210 and the island-shaped dipole layer 212 may be negative polarity dipole layers. In some embodiments, the material of the negative polarity dipole layer is, for example, lanthanum oxide. In some embodiments, when the transistor structure 20 is an NMOS transistor structure and the island-shaped dipole layer 210 and the island-shaped dipole layer 212 are positive polarity dipole layers, the absolute value of the threshold voltage of the transistor structure 20 in an edge region adjacent to the edge E3 of the active region AA2 can be increased, and the absolute value of the threshold voltage of the transistor structure 20 in an edge region adjacent to the edge E4 of the active region AA2 can be increased. In some embodiments, when the transistor structure 20 is a PMOS transistor structure and the island-shaped dipole layer 210 and the island-shaped dipole layer 212 are negative polarity dipole layers, the absolute value of the threshold voltage of the transistor structure 20 in an edge region adjacent to the edge E3 of the active region AA2 can be increased, and the absolute value of the threshold voltage of the transistor structure 20 in an edge region adjacent to the edge E4 of the active region AA2 can be increased.

In some embodiments, in a direction D3 from the edge E3 toward the edge E4, the island-shaped dipole layer 210 may have a width W4, the island-shaped dipole layer 212 may have a width W5, and the active region AA2 may have a width W6. In some embodiments, the width W4 may be 5% to 30% of the width W6. In some embodiments, the width W5 may be 5% to 30% of the width W6.

In the present embodiment, as shown in FIG. 6, in the direction D3 from the edge E3 toward the edge E4, the island-shaped dipole layer 210 and the island-shaped dipole layer 212 may be aligned with each other, but the invention is not limited thereto. In other embodiments, as shown in FIG. 8, in the direction D3 from the edge E3 toward the edge E4, the island-shaped dipole layer 210 and the island-shaped dipole layer 212 are not aligned with each other.

In the present embodiment, as shown in FIG. 6, in a direction D4 from the doped region 204 toward the doped region 206, the island-shaped dipole layer 210 and the island-shaped dipole layer 212 do not extend to two opposite edges (e.g., edge E5 and edge E6) of the gate 202, but the invention is not limited thereto. In other embodiments, as shown in FIG. 9, in the direction D4 from the doped region 204 toward the doped region 206, the island-shaped dipole layer 210 may extend to two opposite edges (e.g., edge E5 and edge E6) of the gate 202, and the island-shaped dipole layer 212 may extend to two opposite edges (e.g., edge E5 and edge E6) of the gate 202.

In the present embodiment, as shown in FIG. 6, the number of the island-shaped dipole layers 210 is, for example, one, and the number of the island-shaped dipole layers 212 is, for example, one, but the invention is not limited thereto. In other embodiments, as shown in FIG. 10, the transistor structure 20 may include a plurality of the island-shaped dipole layers 210 and a plurality of the island-shaped dipole layers 212. The plurality of the island-shaped dipole layers 210 may overlap at the edge E3. The plurality of the island-shaped dipole layers 212 may overlap at the edge E4. In addition, when the transistor structure 20 includes the plurality of the island-shaped dipole layers 210 and the plurality of the island-shaped dipole layers 212, the number of the plurality of the island-shaped dipole layers 210 and the number of the plurality of the island-shaped dipole layers 212 are not limited to the number shown in FIG. 10. Furthermore, the top-view shape of the island-shaped dipole layer 210 and the top-view shape of the island-shaped dipole layer 212 are not limited to the shapes shown in the figures.

In addition, in FIG. 6 to FIG. 10, the same or similar components are denoted by the same reference symbols, and the description thereof is omitted.

Based on the above embodiments, in the transistor structure 20, the island-shaped dipole layer 210 and the island-shaped dipole layer 212 are located between the gate 202 and the gate dielectric layer 208 and are separated from each other. The island-shaped dipole layer 210 overlaps the edge E3 of the active region AA2, and the island-shaped dipole layer 212 overlaps the edge E4 of the active region AA2. Therefore, the absolute value of the threshold voltage of the transistor structure 20 in an edge region adjacent to the edge E3 of the active region AA2 can be increased, and the absolute value of the threshold voltage of the transistor structure 20 in an edge region adjacent to the edge E4 of the active region AA2 can be increased. In this way, the current double hump effect can be effectively reduced, thereby preventing the current double hump effect from causing the adverse effect on the electrical property of the transistor structure 20.

In summary, in a transistor structure of some embodiments of the invention, a dipole layer is located between a gate and a gate dielectric layer, the dipole layer includes a first opening and a second opening, the first opening overlaps a first edge of an active region, and the second opening overlaps a second edge of the active region. Therefore, the absolute value of the threshold voltage of the transistor structure in an edge region adjacent to the first edge of the active region can be increased, and the absolute value of the threshold voltage of the transistor structure in an edge region adjacent to the second edge of the active region can be increased. In this way, the current double hump effect can be effectively reduced, thereby preventing the current double hump effect from causing the adverse effect on the electrical property of the transistor structure.

In transistor structures of other embodiments of the invention, a first island-shaped dipole layer and a second island-shaped dipole layer are located between a gate and a gate dielectric layer and are separated from each other, the first island-shaped dipole layer overlaps a first edge of an active region, and the second island-shaped dipole layer overlaps a second edge of the active region. Therefore, the absolute value of the threshold voltage of the transistor structure in an edge region adjacent to the first edge of the active region can be increased, and the absolute value of the threshold voltage of the transistor structure in an edge region adjacent to the second edge of the active region can be increased. In this way, the current double hump effect can be effectively reduced, thereby preventing the current double hump effect from causing the adverse effect on the electrical property of the transistor structure.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A transistor structure, comprising:
a substrate comprising an active region, wherein the active region comprises a first edge and a second edge opposite to each other;
a gate located on the substrate in the active region and overlapping the first edge and the second edge;
a first doped region and a second doped region located in the substrate in the active region on two sides of the gate;
a gate dielectric layer located between the gate and the substrate; and
a dipole layer located between the gate and the gate dielectric layer, wherein the dipole layer comprises a first opening and a second opening, the first opening overlaps the first edge, and the second opening overlaps the second edge.

2. The transistor structure according to claim 1, wherein the dipole layer extends from the first edge to the second edge and overlaps the first edge and the second edge.

3. The transistor structure according to claim 1, wherein in a direction from the first edge toward the second edge, the first opening and the second opening are aligned with each other.

4. The transistor structure according to claim 1, wherein in a direction from the first edge toward the second edge, the first opening and the second opening are not aligned with each other.

5. The transistor structure according to claim 1, wherein in a direction from the first doped region toward the second doped region, the first opening extends through the dipole layer and the second opening extends through the dipole layer to divide the dipole layer into portions separated from each other.

6. The transistor structure according to claim 1, wherein the dipole layer comprises a plurality of the first openings and a plurality of the second openings, the plurality of the first openings overlap the first edge, and the plurality of the second openings overlap the second edge.

7. The transistor structure according to claim 1, wherein the dipole layer comprises a negative polarity dipole layer or a positive polarity dipole layer.

8. The transistor structure according to claim 7, wherein a material of the negative polarity dipole layer comprises lanthanum oxide.

9. The transistor structure according to claim 7, wherein a material of the positive polarity dipole layer comprises aluminum oxide.

10. The transistor structure according to claim 1, wherein the gate comprises a metal gate, and the gate dielectric layer comprises a high dielectric constant dielectric layer.

11. The transistor structure according to claim 1, further comprising:
an isolation structure located in the substrate and defining the active region, wherein the first opening overlaps the isolation structure, and the second opening overlaps the isolation structure.

12. A transistor structure, comprising:
a substrate comprising an active region, wherein the active region comprises a first edge and a second edge opposite to each other;
a gate located on the substrate in the active region and overlapping the first edge and the second edge;
a first doped region and a second doped region located in the substrate in the active region on two sides of the gate;
a gate dielectric layer located between the gate and the substrate; and
a first island-shaped dipole layer and a second island-shaped dipole layer located between the gate and the gate dielectric layer and separated from each other, wherein the first island-shaped dipole layer overlaps the first edge, and the second island-shaped dipole layer overlaps the second edge.

13. The transistor structure according to claim 12, wherein in a direction from the first edge toward the second edge, the first island-shaped dipole layer and the second island-shaped dipole layer are aligned with each other.

14. The transistor structure according to claim 12, wherein in a direction from the first edge toward the second edge, the first island-shaped dipole layer and the second island-shaped dipole layer are not aligned with each other.

15. The transistor structure according to claim 12, in a direction from the first doped region toward the second doped region, the first island-shaped dipole layer extends to two opposite edges of the gate, and the second island-shaped dipole layer extends to the two opposite edges of the gate.

16. The transistor structure according to claim 12, comprising a plurality of the first island-shaped dipole layers and a plurality of the second island-shaped dipole layers, the plurality of the first island-shaped dipole layers overlap the first edge, and the plurality of the second island-shaped dipole layers overlap the second edge.

17. The transistor structure according to claim 12, wherein the first island-shaped dipole layer and the second island-shaped dipole layer comprise positive polarity dipole layers.

18. The transistor structure according to claim 12, wherein the first island-shaped dipole layer and the second island-shaped dipole layer comprise negative polarity dipole layers.

19. The transistor structure according to claim 12, wherein the gate comprises a metal gate, and the gate dielectric layer comprises a high dielectric constant dielectric layer.

20. The transistor structure according to claim 12, further comprising:
an isolation structure located in the substrate and defining the active region, wherein the first island-shaped dipole layer overlaps the isolation structure, and the second island-shaped dipole layer overlaps the isolation structure.
